(19) United States
(12) Patent Application Publication
(10) Pub. No.: US 2023/0274939 A1
(43) Pub. Date: Aug. 31, 2023

(54) ATOMIC LAYER ETCHING OF A SEMICONDUCTOR, A METAL, OR A METAL OXIDE WITH SELECTIVITY TO A DIELECTRIC

(71) Applicant: Lam Research Corporation, Fremont, CA (US)

(72) Inventors: Thorsten Bernd Lill, Kalaheo, HI (US); Andreas Fischer, Castro Valley, CA (US); Aaron Lynn Routzahn, Fremont, CA (US)

(21) Appl. No.: 18/002,788

(22) PCT Filed: Aug. 20, 2021
(86) PCT No.: PCT/US2021/046878

§ 371 Date: Dec. 21, 2022

Related U.S. Application Data
(60) Provisional application No. 62/706,703, filed on Sep. 3, 2020.

(51) Int. Cl. H01L 21/3065; H01J 37/32

(52) U.S. Cl. CPC H01L 21/3065; H01J 37/32449; H01J 2237/334

(57) ABSTRACT

Semiconductor processing methods and apparatuses are provided. Some methods include providing a substrate to a processing chamber, the substrate having a semiconductor portion and a dielectric portion, modifying the semiconductor portion of the substrate selective to the dielectric portion of the substrate by flowing a first process gas comprising a first halogen species onto the substrate and providing a first activation energy to cause the first halogen species to preferentially adsorb on the semiconductor portion relative to the dielectric portion to form a first halogenated semiconductor, and removing the first halogenated semiconductor by flowing a second process gas comprising a second halogen species onto the substrate and providing a second activation energy, without providing a plasma, to cause the second halogen species to react with the first halogenated semiconductor and cause the first halogenated semiconductor to desorb from the substrate.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor fabrication often involves patterning schemes and other processes whereby some materials are selectively etched to prevent etching of other exposed surfaces of a substrate. As device geometries become smaller and smaller, high etch selectivity processes are desirable to achieve effective etching of desired materials without plasma assistance.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

The systems, methods and devices of this disclosure each have several innovative aspects, no single one of which is solely responsible for the desirable attributes disclosed herein. Included among these aspects are at least the following implementations, although further implementations may be set forth in the detailed description or may be evident from the discussion provided herein.

In some embodiments, a method may be provided. The method may include providing a substrate to a processing chamber, the substrate having a semiconductor portion and a dielectric portion, modifying the semiconductor portion of the substrate selective to the dielectric portion of the substrate by flowing a first process gas comprising a first halogen species onto the substrate and providing a first activation energy to cause the first halogen species to preferentially adsorb on the semiconductor portion relative to the dielectric portion to form a first halogenated semiconductor, and removing the first halogenated semiconductor by flowing a second process gas comprising a second halogen species onto the substrate and providing a second activation energy, without providing a plasma, to cause the second halogen species to react with the first halogenated semiconductor and cause the first halogenated semiconductor to desorb from the substrate.

In some embodiments, during the removing the second halogen species may react with the first halogenated semiconductor to convert the first halogenated semiconductor to a second halogenated semiconductor, and the desorption of the first halogenated semiconductor may include desorption of the second halogenated semiconductor.

In some such embodiments, the second halogenated semiconductor may be more volatile than the first halogenated semiconductor.

In some such embodiments, the first halogen species may include chlorine, the first halogenated semiconductor comprises silicon tetrachloride (SiCl₄), the second halogen species may include fluorine, and the second halogenated semiconductor may include silicon tetrafluoride (SiF₄).

In some embodiments, the semiconductor portion may include one or more of silicon, germanium, silicon-germanium, or a doped silicon.

In some embodiments, the dielectric portion may include one or more of an oxide or a nitride.

In some embodiments, at the first activation energy, the semiconductor portion may be halogenated by the first halogen species without halogenating the dielectric portion.

In some such embodiments, at the second activation energy, the first halogenated semiconductor may be removed by a reaction with the second halogen species without removing the dielectric portion.

In some embodiments, providing the first activation energy may be provided by heating the substrate to a temperature.

In some such embodiments, the first temperature may be greater than about 100° C.

In some such embodiments, the first activation energy may be provided by heating the substrate and by a plasma, and the first temperature may be less than or equal to about 250° C.

In some further such embodiments, the first temperature may be less than or equal to about 150° C.

In some embodiments, providing the first activation energy may be provided by a plasma.

In some embodiments, the second activation energy may be provided, without using a plasma, by heating the substrate to a temperature.

In some such embodiments, the temperature may be greater than or equal to about 100° C.

In some embodiments, the modifying may be performed while the substrate is maintained at a temperature less than or equal to about 150° C.

In some embodiments, the removing may be performed while the substrate is maintained at a temperature greater than or equal to about 100° C.

In some embodiments, the first and second halogen species may each include a different halogen species selected from the group consisting of fluorine, chlorine, bromine, and iodine.

In some embodiments, the first halogen species may include chlorine, and the second halogen species may include fluorine.

In some embodiments, the first halogen species may include fluorine, and the second halogen species may include chlorine.

In some embodiments, the first process gas may include chlorine (Cl₂), and the second process gas may include hydrogen fluoride (HF).

In some embodiments, the semiconductor portion may include silicon.

In some such embodiments, the dielectric portion may include a silicon oxide or a silicon nitride.

In some embodiments, the modification of the semiconductor portion and/or the removal of the first halogenated semiconductor may occur isotropically.

In some embodiments, the semiconductor portion may not include a silicon oxide.

In some embodiments, the method may further include flowing, before or during the removing, a catalyst onto the substrate, and the catalyst may be configured to assist with the reaction between the second halogen species and the first halogenated semiconductor.

In some embodiments, a method may be provided. The method may include providing a substrate to a processing chamber, the substrate having a metal-containing portion and a dielectric portion, modifying the metal-containing portion of the substrate selective to the dielectric portion of the substrate by flowing a first process gas comprising a first halogen species onto the substrate and providing a first activation energy to cause the first halogen species to preferentially adsorb on the metal-containing portion relative to the dielectric portion to form a halogenated metal-containing portion, and removing the halogenated metal-containing portion by flowing a second process gas comprising a second halogen species onto the substrate and providing a second activation energy, without providing a plasma, to cause the second halogen species to react with the halogenated metal-containing portion and cause the halogenated metal-containing portion to desorb from the substrate.

In some embodiments, the metal-containing portion may include a metal or a metal oxide.

In some embodiments, at the first activation energy, the metal-containing portion may be halogenated by the first halogen species without halogenating the dielectric portion.

In some embodiments, at the second activation energy, the first halogenated metal-containing portion may be removed by a reaction with the second halogen species without removing the dielectric portion.

In some embodiments, the first halogen species may include fluorine, and the second halogen species may include chlorine.

In some embodiments, an apparatus for semiconductor processing may be provided. The apparatus may include a processing chamber that includes chamber walls that at least partially bound a chamber interior, and substrate support configured to support a substrate in the chamber interior, a process gas unit configured to flow a first process gas comprising a first halogen species and a second process gas comprising a second halogen species into the chamber interior and onto the substrate in the chamber interior, in which the substrate has a semiconductor portion and a dielectric portion, a first energy unit configured to provide a first activation energy to the substrate on the substrate support, a second energy unit configured to provide a second activation energy to the substrate on the substrate support; and a controller with instructions that are configured to cause the process gas unit to flow the first process gas onto the substrate, cause, while flowing the first process gas onto the substrate, the first energy unit to provide the first activation energy to the substrate to cause the first halogen species to preferentially adsorb on the semiconductor portion relative to the dielectric portion to form a halogenated semiconductor, cause the process gas unit to flow the second process gas onto the substrate, and cause, while flowing the second process gas onto the substrate, the second energy unit to provide the second activation energy to the substrate to cause the second halogen species to react with the halogenated semiconductor and cause the halogenated semiconductor to desorb from the substrate.

In some embodiments, the first energy unit may be a heater and the second energy unit may be the heater.

In some embodiments, the first energy unit may be configured to generate a plasma, the second energy unit may be a heater, the first activation energy may be a plasma energy generated by the first energy unit, and the second activation energy may be provided by causing the heater to heat the substrate to a first temperature.

In some embodiments, the first temperature may be greater than about 100° C.

### BRIEF DESCRIPTION OF THE DRAWINGS

FIG. 1 depicts an example process flow diagram for performing operations in accordance with disclosed embodiments.

FIG. 2 provides a second example process flow diagram for performing operations in accordance with disclosed embodiments.

FIG. 3 depicts an example schematic illustration of an ALE cycle according to disclosed embodiments.

FIG. 4A depicts representational illustrations of binding energies of various elements during a modification operation.

FIG. 4B depicts representational illustrations of binding energies of various elements during a removal operation.

FIG. 5 depicts an example substrate processing chamber in accordance with disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Introduction and Context

Semiconductor fabrication processes often involve patterning and etching of various materials, including conductors, semiconductors, and dielectrics. Some examples include conductors, such as metals, metal oxides, or carbon; semiconductors, such as silicon, doped silicon, or germanium; and dielectrics, such as silicon oxide, aluminum dioxide, zirconium dioxide, hafnium dioxide, silicon nitride, and titanium nitride. Atomic layer etching (“ALE”) processes remove thin layers of material using sequential self-limiting reactions. Generally, an ALE cycle is the minimum set of operations used to perform an etch process one time, such as etching a monolayer. The result of one ALE cycle is that at least some of a film layer on a substrate surface is etched. Typically, an ALE cycle includes a modification operation to form a reactive layer, followed by a removal operation to remove or etch only this reactive layer. The cycle may include certain ancillary operations such as removing one of the reactants or byproducts. Generally, a cycle contains one instance of a unique sequence of operations.

As an example, an ALE cycle may include the following operations: (i) delivery of a reactant gas, (ii) purging of the reactant gas from the chamber, (iii) delivery of a removal gas and an optional plasma, and (iv) purging of the chamber. In some embodiments, etching may be performed nonconformally. The modification operation generally forms a thin, reactive surface layer with a thickness less than the un-modified material. In an example modification operation, a substrate may be chlorinated by introducing chlorine into the chamber. Chlorine is used as an example etchant species or etching gas, but it will be understood that a different etching gas may be introduced into the chamber. The etching gas may be selected depending on the type and chemistry of the substrate to be etched. A plasma may be ignited and chlorine reacts with the substrate for the etching process; the chlorine may react with the substrate or may be adsorbed onto the surface of the substrate. The species generated from a chlorine plasma can be generated directly by forming a plasma in the process chamber housing the substrate or they can be generated remotely in a process chamber that does not house the substrate, and can be supplied into the process chamber housing the substrate.

In some instances, a purge may be performed after a modification operation. In a purge operation, non-surface-bound active chlorine species may be removed from the process chamber. This can be done by purging and/or evacuating the process chamber to remove the active species, without removing the adsorbed layer. The species generated in a chlorine plasma can be removed by simply stopping the plasma and allowing the remaining species decay, optionally combined with purging and/or evacuation of the chamber. Purging can be done using any inert gas such as N2, Ar, Ne, He and their combinations.

In a removal operation, the substrate may be exposed to an energy source to etch the substrate by directional sputtering (this may include activating or sputtering gas or chemically reactive species that induce removal). In some embodiments, the removal operation may be performed by ion bombardment using argon or helium ions. During removal, a bias may be optionally turned on to facilitate directional sputtering. In some embodiments, ALE may be isotropic; in some other embodiments ALE is not isotropic when ions are used in the removal process.

In various examples, the modification and removal operations may be repeated in cycles, such as about 1 to about 30 cycles, or about 1 to about 20 cycles. Any suitable number of ALE cycles may be included to etch a desired amount of film. In some embodiments, ALE is performed in cycles to etch about 1 Å to about 50 Å of the surface of the layers on the substrate. In some embodiments, cycles of ALE etch between about 2 Å and about 50 Å of the surface of the layers on the substrate. In some embodiments, each ALE cycle may etch at least about 0.1 Å, 0.5 Å, or 1 Å.

In some instances, prior to etching, the substrate may include a blanket layer of material, such as silicon or germanium. The substrate may include a patterned mask layer previously deposited and patterned on the substrate. For example, a mask layer may be deposited and patterned on a substrate including a blanket amorphous silicon layer. The layers on the substrate may also be patterned. Substrates may have “features” such as via or contact holes, which may be characterized by one or more of narrow and/or re-entrant openings, constrictions within the feature, and high aspect ratios. One example of a feature is a hole or via in a semiconductor substrate or a layer on the substrate. Another example is a trench in a substrate or layer. In various instances, the feature may have an under-layer, such as a barrier layer or adhesion layer. Non-limiting examples of under-layers include dielectric layers and conducting layers, e.g., silicon oxides, silicon nitrides, silicon carbides, metal oxides, metal nitrides, metal carbides, and metal layers.

In some instances, the use of plasma during etching may present challenges or disadvantages. For instance, it is generally desirable to create the same plasma conditions for each ALE cycle of a single substrate as well as for all substrates in a batch, but it can be difficult to repeatedly recreate the same plasma conditions due to some plasmas changing due to accumulation of material in the process chamber. Additionally, many ALE processes may cause damage to exposed components of the substrate, such as silicon oxide, may cause defects, and may increase the top-to-bottom ratio of a pattern and increase the pattern loading. Defects may lead to pattern-missing to the extent that the device may be rendered useless. Some plasma-assisted ALE may also utilize small radicals, i.e., deeply dissociated radicals, that are more aggressive which may cause them to remove more material than may be desired, thereby reducing the selectivity of this etching. As a result, many ALE techniques may often be unsuitable for selectively etching some materials, such as etching semiconductor material relative to dielectric material.

In some implementations, it is desirable to etch a substrate’s semiconductor material without, or with limited, etching of the substrate’s dielectric material. During the processing of some substrates, the substrate may have both semiconductor material, such as silicon, doped silicon, or germanium, as well as dielectrics or other materials and it may be desirable to remove only the semiconductor material. However, it can be challenging to etch semiconductor material without also etching the dielectric.

For example, many ALE techniques may not be capable of etching a semiconductor with silicon semiconductor portions and silicon oxide dielectric portions, with selectivity to the dielectric, such as the silicon oxide. Such techniques may use an oxygen plasma to oxidize the silicon in a modifying step/operation. In the removal operation, hydrogen fluoride (HF) may be flowed onto the substrate to remove the silicon that was oxidized in the modifying step, but this HF reacts with both the silicon that was oxidized in the modifying step and the silicon oxide dielectric, thereby removing both the semiconductor and the dielectric. These ALE techniques therefore do not have selectivity to the silicon oxide dielectric. In another example, many ALE techniques may not be capable of etching a substrate’s silicon semiconductor portions with selectivity to the substrate’s silicon nitride dielectric portions. During the modifying operation, the oxygen plasma may oxidize both the silicon semiconductor portions and the silicon nitride dielectric portions and causes both these portions to be removed when the HF is flowed onto the substrate in the removal operation. In yet other examples, many ALE techniques may not be capable of etching a metal or metal oxide with selectivity to the dielectric portions. Accordingly, the novel techniques described herein etch a semiconductor, a metal, or a metal oxide with selectivity to a dielectric.

### Selective ALE Techniques

Provided herein are methods and apparatuses for etching a semiconductor with selectivity to a dielectric by preferentially adsorbing a halogen species with the semiconductor relative to the dielectric, i.e., without adsorbing with the dielectric portion, and removing the halogenated semiconductor with desorption. In a modifying operation having a particular set of process conditions, a halogen species is caused to preferentially adsorb on the semiconductor without adsorbing, and thus without halogenating, the dielectric. This preferential adsorption may be driven, in some instances and at least in part, by the binding energies of the halogen species, semiconductor, and dielectric. Chemical adsorption, or “chemisorption,” of the halogen species to other molecules and compounds is an energy dependent (e.g., a temperature dependent) chemical reaction. Because of this, the halogen species and its corresponding binding energy may be selected such that the halogen species’ binding energy is greater than the semiconductor’s binding energy, thereby enabling the halogen species to adsorb on the semiconductor, but is less than the dielectric’s binding energy, thereby preventing (or at least limiting) the halogen species from adsorbing on the dielectric. In some embodiments, an activation energy may be provided to assist with overcoming the activation barrier for the halogen species to adsorb on the semiconductor. This activation energy may be provided with thermal energy, radical energy, or both, which may include heating the substrate and/or generating a plasma to radicalize the halogen species.

It should be noted that the adsorption of the halogen species may be imperfect. For example, the halogen species may not adsorb on all of the semiconductor and it may adsorb on some of the dielectric. However, the preferential outcome of this adsorption is that the halogen species adsorbs on the semiconductor and not the dielectric; the halogen species therefore halogenates the semiconductor without halogenating the dielectric.

It should also be noted that in some embodiments, the substrate may have a metal-containing portion, that may include a metal or metal oxide, not a semiconductor, that is removed from the substrate with selectivity to the substrate’s dielectric. This may include, for instance a substrate having a metal-containing portion with a titanium or titanium oxide and a dielectric, such as a silicon oxide.

Once the halogen species adsorbs on the semiconductor to form a first halogenated semiconductor, during a removal operation this first halogenated semiconductor may be preferentially desorbed using a second halogen species. In some instances, this second halogen species reacts with and converts the first halogenated semiconductor to a more volatile second halogenated semiconductor that can be desorbed from the substrate relative to the dielectric portion, i.e., without removing the dielectric portion or with removing a limited amount of the dielectric. This reaction and conversion are preferential reactions in which the second halogen species preferentially reacts with the first halogenated semiconductor and not with the dielectric. This desorption may occur with a second activation energy that may be provided by thermal energy, not a plasma. Similar to the modification operation, the second halogen species and its corresponding binding energy may be selected such that the second halogen species’ binding energy is greater than the first halogenated semiconductor’s binding energy, thereby enabling the second halogen species to react with the first halogenated semiconductor, but is less than the dielectric portion’s binding energy, thereby preventing (or at least limiting) the second halogen species from reacting with the dielectric. A second activation energy, a catalyst, or both may be provided to assist with the reaction between the first halogenated semiconductor and the second halogen species to convert the first halogenated semiconductor to the second halogenated semiconductor.

The removal operation’s process conditions are also selected to cause the preferential desorption of this converted, second halogenated semiconductor relative to the dielectric portion, i.e., without removing the dielectric portion. For instance, the second halogenated semiconductor may desorb from the substrate at an energy level less than the energy level at which the dielectric portion desorbs from the substrate. By providing energy at or below this level, the first halogenated semiconductor is caused to selectively desorb from the substrate. This advantageously allows for the etching of the semiconductor with selectivity to the dielectric portion.

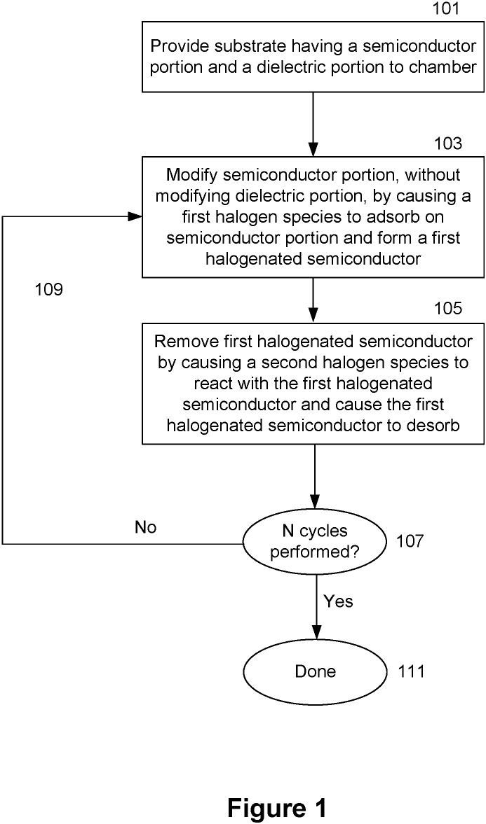

FIG. 1 depicts an example process flow diagram for performing operations in accordance with disclosed embodiments. Each operation of FIG. 1 will be discussed in greater detail below, but in general, operation 101 represents providing a substrate having a semiconductor portion and a dielectric portion to the processing chamber, operation 103 represents modifying the semiconductor portion, selective to the dielectric portion (i.e., with limited or no modification of the dielectric portion such that the dielectric portion is not halogenated or there is limited halogenation of the dielectric portion), by flowing a first halogen species onto the substrate and causing the first halogen species to preferentially adsorb on the semiconductor portion without halogenating the dielectric portion to form a first halogenated semiconductor, and operation 105 represents removing the first halogenated semiconductor by flowing a second halogen species onto the substrate and causing the second halogen species to preferentially react with the first halogenated semiconductor and cause the first halogenated semiconductor to preferentially desorb from the substrate without removing the dielectric portion. In some instances, a single cycle may include operations 103 and 105, and multiple layers of material may be etched from the substrate by performing multiple cycles.

In operation 101, a substrate is provided into a processing chamber. The substrate contains one or more semiconductor portions and one or more dielectric portions. These semiconductor portions and dielectric portions are commonly used materials in processing substrates, both during processing operations and as part of a completed, processed substrate. For example, dielectric material, such as silicon oxide (SiO₂), may be used as a mask during some etching and/or deposition processes, as well as a part of a device on a fully processed substrate; similarly, semiconductor material may be used to build devices and structures. It is desirable in some processing operations to etch a semiconductor material without etching, or with limited etching of, a dielectric material. For instance, it may be desirable to remove some semiconductor material without removing a hard mask that comprises a dielectric, such as a silicon oxide. When provided into the processing chamber, the substrate includes layers of material and exposed surfaces that may be a uniform layer of material or may be a non-uniform layer that includes different molecules and elements. These exposed surfaces may include the semiconductor portions and dielectric portions.

As noted above, the semiconductor portion may include silicon, a doped silicon, or germanium. The doped silicon may include aluminum, boron, and phosphorus, for instance. In some embodiments, the semiconductor portion does not comprise an oxide or a nitride, such as silicon oxide or silicon nitride. The dielectric portion may include an oxide, a nitride, silicon oxide, aluminum dioxide, zirconium dioxide, hafnium dioxide, silicon nitride, or titanium nitride, for example.

After the substrate is provided into the processing chamber in operation 101, a modifying operation 103 may be performed. This operation 103 includes the preferential adsorption of a first halogen species on the semiconductor portion with limited to no adsorption of the first halogen species on the dielectric portion. This adsorption forms a first halogenated semiconductor and this adsorption may be considered chemisorption. The first halogen species is flowed onto the exposed surfaces of the substrate that includes the semiconductor portions and dielectric portions. The halogen species and its binding energy are chosen to enable the selective and preferential adsorption such that, based on the make-up of the semiconductor portions and dielectric portions, the halogen species has a binding energy greater than the semiconductor and less than the dielectric, which enables the preferential adsorption with the semiconductor and not the dielectric. The semiconductor portions are therefore halogenated by the halogen species without halogenating the dielectric portion; as noted herein, although not intended, there may be some limited halogenation of the dielectric portion. For example, a halogen species comprising chloride may have a binding energy of about 4.2 electronvolts (eV), a semiconductor portion comprising silicon may have a binding energy of about 3.4 eV, and a dielectric portion comprising a silicon oxide may have a binding energy of about 6.4 eV. In this example, the chloride may preferentially adsorb with the semiconductor because the chloride’s binding energy of about 4.2 eV is greater than the silicon’s binding energy of about 3.4 eV, and therefore may not adsorb (or may adsorb in a limited amount) on the dielectric because the chloride’s binding energy of about 4.2 eV is less than the silicon oxide’s binding energy of about 6.4 eV. In this example, the silicon is halogenated without halogenating the silicon oxide.

In some implementations, an activation energy may be provided during the modifying operation 103. This activation energy may provide, at least in part, enough energy to overcome the activation barrier for adsorption of the halogen species on the semiconductor portion, but not enough to overcome the activation barrier for adsorption between the halogen species and the dielectric portion. In some instances, the activation energy may be a thermal energy provided by heating the substrate to a first temperature and maintaining the substrate at that temperature for at least a part or all of the modifying operation 103. The heat may be provided by heating a substrate support (e.g., a pedestal or electrostatic chuck) supporting the substrate which in turn heats the substrate. The substrate may therefore be maintained at the first temperature during the modifying operation 103. In some embodiments, the first temperature may be greater than about 50° C. or about 100° C., or it may be less than about 150° C.; it may also range between about 50° C. and 400° C., between about 75° C. and 200° C., between about 75° C. and 150° C., between about 100° C. and 250° C., or between about 100° C. and 200° C.

In some implementations, the activation energy during the modifying operation 103 may be provided by a plasma. This may include generating a plasma to radicalize the halogen species flowed onto the substrate. The plasma may have a low to negligible ion energy which may be accomplished by generating the plasma at a high pressure, such as about 90 or 100 millitorr, and flowing the plasma past a grid which neutralizes some of the plasma’s ion flux. In some embodiments, the plasma may be considered a downstream or transformer coupled plasma (TCP).

In some embodiments, the activation energy is provided during the modification operation 103 by both the plasma and the heating of the substrate. This may include, in some embodiments, maintaining the substrate at a temperature less than or equal to about 250° C., 200° C., 150° C., or 100° C. In some instances, it may be advantageous to use a plasma while the substrate is maintained at a temperature less than or equal to 100° C.

The halogen species flowed onto the substrate in the modifying operation 103 may be fluorine, chlorine, bromine, or iodine. In some embodiments, the halogen species may be a part of a process gas flowed onto the substrate, and this process gas may include other elements, such as a carrier gas that includes nitrogen, argon, helium, or neon, for instance. The halogen species may be flowed at various flowrates onto the substrate, such as 50 to 2,000 sccm.

In some embodiments, the modifying operation may be isotropic. This may enable the adsorption of the halogen species on the semiconductor portion in a non-directional manner.

After operation 103, a removal operation 105 may be performed. The removal operation may include flowing a second halogen species, different than the first halogen species, onto the substrate to react with the first halogenated semiconductor, not the dielectric portion, and causing the first halogenated semiconductor to desorb, relative to the dielectric, from the substrate, i.e., removing the first halogenated semiconductor without removing the dielectric portion. This removal operation may therefore include two aspects, the first being the preferential reaction between the second halogen species and the first halogenated semiconductor, not a reaction between (or a limited amount of reaction between) the second halogen species and the dielectric portion, to convert the first halogenated semiconductor to the second halogenated semiconductor; the second being the preferential desorption of the second halogenated semiconductor without the desorption of the dielectric portion.

The preferential reaction between the second halogen species and the first halogenated semiconductor to convert the first halogenated semiconductor to a second halogenated semiconductor without reacting with the dielectric portion (i.e., relative to the dielectric), may be based, at least in part, on the binding energies of these elements. In some embodiments, the binding energy of the second halogen species may be greater than the binding energy of the first halogenated semiconductor, thereby allowing them to react and convert the first halogenated semiconductor to the second halogenated semiconductor; the binding energy of the second halogen species may also be less than the binding energy of the dielectric portion, thereby preventing the second halogen species from reacting with the dielectric portion. The resulting second halogenated semiconductor may be more volatile than the first halogenated semiconductor. This volatility, at least in part, enable the second halogenated semiconductor to desorb from the substrate.

A second activation energy provided during the removal operation may also, at least in part, enable and drive the preferential desorption of the second halogenated semiconductor without causing the desorption of the dielectric portion (i.e., relative to the dielectric), from the substrate. This second activation energy may provide, at least in part, enough energy to overcome the activation barrier for desorption of the second halogenated semiconductor, but not enough to overcome the activation barrier for desorption of the dielectric portion. This energy may be thermal energy, not a plasma, provided by heating and maintaining the substrate to a second temperature. In some embodiments, the second temperature may be greater than or equal to about 100° C., 150° C., 200° C., or 250° C., for example. As noted above, the heat may be provided by heating a substrate support (e.g., a pedestal or electrostatic chuck) supporting the substrate which in turn heats the substrate. The substrate may therefore be maintained at the first temperature during the removal operation.

In some embodiments, the second activation energy provided by heating the wafer further enables the above-mentioned reaction and desorption by removing hydroxy groups (water adsorbates) that may be present on the substrate, and preventing the substrate from hydroxylating during the removal operation. The presence and formation of hydroxy groups may adversely affect the removal operation because they may react with the second halogen species to thereby cause an unwanted reaction with the dielectric portion and further cause the unwanted formation of additional hydroxy groups. For example, if the second halogen species is fluorine and flowed onto the substrate as hydrogen fluoride (HF), and the substrate includes silicon oxide (SiO₂) and a hydroxy group, such as water (H₂O), with an OH bond at the substrate surface, then the HF will react with the hydroxy group and form SiF₄ and H₂O. This reaction is unwanted because the SiF₄ will desorb from the substrate, including at the second activation energy of the removal operation, and the newly formed H₂O will hydroxylate the surface again which will continue the reaction between the HF, the SiO₂, and newly formed H₂O to continue forming SiF₄ and removing the SiO₂ dielectric. Accordingly, the second activation energy provided by heating the wafer to, for instance, greater than or equal to about 100° C., 150° C., 200° C., or 250° C., may remove the unwanted hydroxy groups from the substrate.

In some embodiments, the removal operation may be isotropic. This may enable the reaction of the second halogen species with the first halogenated semiconductor, and the desorption, in non-directional manners.

The second halogen species flowed onto the substrate in the removal operation 105 may be fluorine, chlorine, bromine, or iodine. In some embodiments, the second halogen species may be a part of a second process gas flowed onto the substrate, and this second process gas may include other elements, such as a carrier gas that includes nitrogen, argon, helium, or neon, for instance. The second halogen species may be flowed at various flowrates onto the substrate, such as 50 to 2,000 sccm.

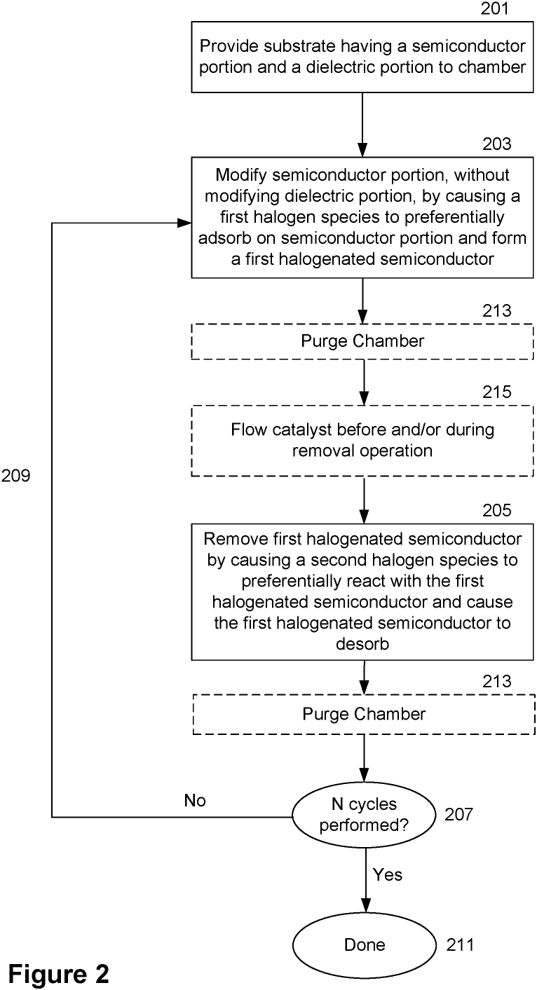

The techniques provided herein may, in some embodiments, include additional optional operations. FIG. 2 provides a second example process flow diagram for performing operations in accordance with disclosed embodiments. Here, operations 201, 203, 205, 207, 209, and 211 are the same as operations 101, 103, 105, 107, 109, and 111 described above. This second example technique includes optional purge operations and an optional catalyst operation.

In an optional purge operation, the chamber may be purged at various times during or after an ALE cycle, including after the modification operation, after the removal operation, or both. FIG. 2 depicts an optional purge operation 213A being performed after the modification operation 203 and another optional purge operation being performed after the removal operation 205. In a purge operation, non-surface-bound material may be removed from the process chamber. This can be done by purging and/or evacuating the process chamber to remove material, such as the halogen species, without removing the adsorbed layer. The species generated in a plasma can be removed by simply stopping the plasma and allowing the remaining species decay, optionally combined with purging and/or evacuation of the chamber. Purging can be done using any inert gas such as N2, Ar, Ne, He and their combinations.

In operation 215, a catalyst may be flowed onto the substrate before and/or during the removal operation 205 to assist with the reaction between the second halogen species and the first halogenated semiconductor. For example, this catalyst may assist with overcoming the activation barrier of the reaction between the second halogen species and the first halogenated semiconductor.

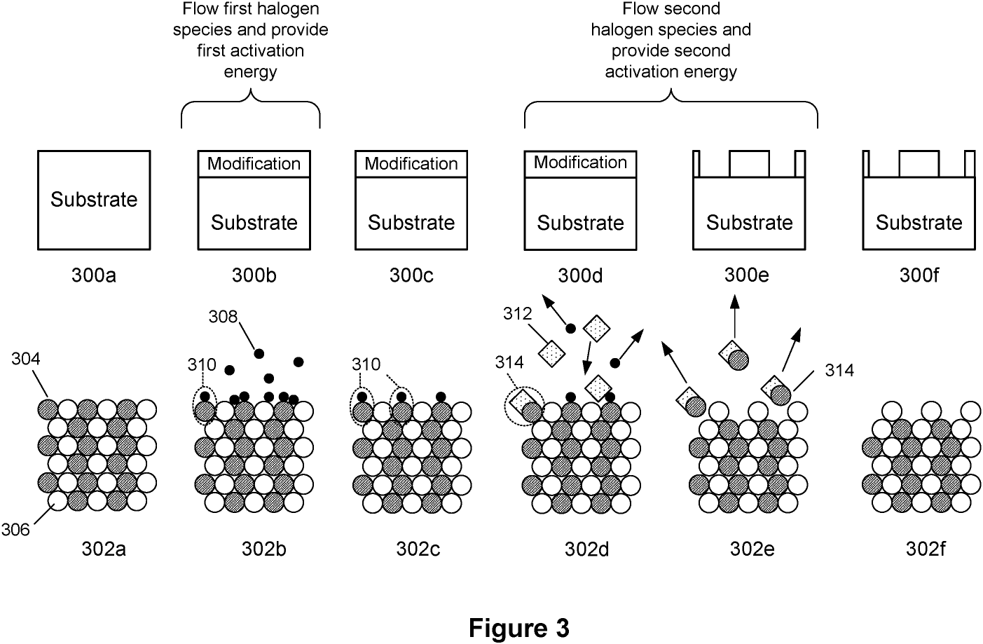

FIG. 3 depicts an example schematic illustration of an ALE cycle according to disclosed embodiments. Diagrams 300a-300f show an ALE cycle. In 300a, the substrate is provided that includes semiconductor portions and dielectric portions. In 300b, the semiconductor in one or more surface layers of the substrate is modified to a halogenated semiconductor by flowing a first halogen species onto the substrate and, in some embodiments, while providing a first activation energy. In 300c, the next step may be prepared, which may include flowing a process gas, purging the chamber, heating the substrate, or cooling the substrate. In 300d, the second halogen species is flowed onto the substrate to react with the halogenated first semiconductor and form a second halogenated semiconductor, and while a second activation energy, that is not a plasma, is provided. In 300e, the second halogenated semiconductor is etched by desorption of the second halogenated semiconductor without desorbing the dielectric portion. In 300f, the desired material has been removed.

Similarly, diagrams 302a-302f show an example of a thermal ALE cycle for preferentially etching a semiconductor with selectivity to a dielectric. In 302a, the substrate is provided, which includes the semiconductor portion 304 (a shaded circle) and dielectric portion 306 molecules (an unshaded circle). One surface layer of the substrate is illustrated to include both the semiconductor portion 304 and the dielectric portion 306. In 302b, the first halogen species 308 (depicted as black dots) is introduced to the substrate which preferentially adsorbs on the semiconductor portion 304, not the dielectric portion 306 (i.e., without adsorbing, and thus without halogenating, the dielectric portion 306), while the first activation energy is provided, e.g., thermal energy, plasma energy, or both. The schematic in 302b shows that the first halogen species 308 is adsorbed onto the semiconductor portion 304 to form the first halogenated semiconductor 310, one of which is identified within a dashed ellipse; the first halogenated semiconductor 310 includes a shaded circle that represents the semiconductor portion 304 and the solid black circle that represents the first halogen species 308. In 302c, after the first halogenated semiconductor 310 is formed, the first halogen species may be optionally purged from the chamber.

In 302d, which is a part of the removal operation, a second halogen species 312 (represented by a shaded diamond) is flowed onto the substrate; this second halogen species preferentially reacts with the first halogenated semiconductor 310, relative to the dielectric portion 306 (i.e., without reacting with the dielectric portion 306), to convert it to a second halogenated semiconductor 314 (shown as a grouping of the diamond and shaded circle, one of which is identified in a dotted ellipse labeled 314) which is volatile. As stated above, the second activation energy (not a plasma) is provided during this flowing in order to enable the reaction between the second halogen species 312 and the first halogenated semiconductor 310 and prevent unwanted reactions with the dielectric portion 306. In 300e, the second halogenated semiconductor 314, not the portion dielectric 306, is removed from the substrate by desorption while continuing to provide the second activation energy; this is equivalent to etching of the substrate. In 302f, the chamber is purged and the byproducts are removed.

This example results in the selective etching of the semiconductor from the substrate because the first and second halogen species, as well as the first and second activation energies, were selected to react with and remove the semiconductor portion, not the dielectric portion, from the layer of material on the substrate. Although shown separately, in some embodiments, diagrams 302d and 302e represent a single removal operation.

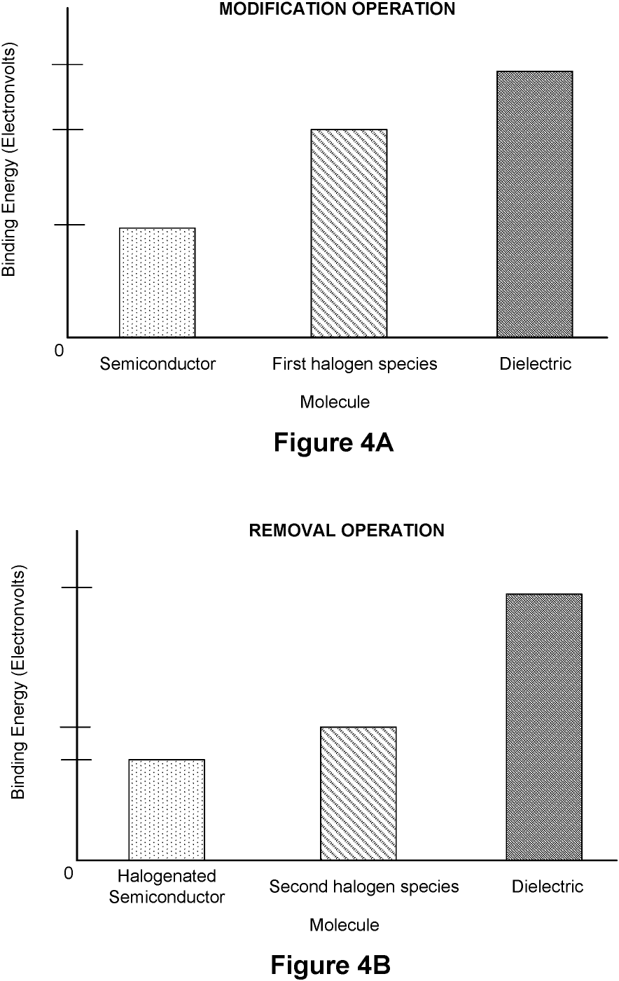

As described above, the modification and removal operations may be driven in some implementations, at least in part, by the binding energies of the halogen species, semiconductor portion, and dielectric portion. FIG. 4A depicts representational illustrations of binding energies of various elements during a modification operation and FIG. 4B depicts representational illustrations of binding energies of various elements during a removal operation. In each Figure, the horizontal axis lists the molecule and the vertical axis is binding energy in electronvolts. As stated above and seen in FIG. 4A, the binding energy of the halogen species used in the modification operation is greater than the binding energy of the semiconductor portion and less than the binding energy of the dielectric portion. Similarly, as seen in FIG. 4B, the binding energy of the second halogen species used in the removal operation is greater than the binding energy of the first halogenated semiconductor and less than the binding energy of the dielectric portion. As further illustrated in FIGS. 4A and 4B, the binding energy of the second halogen species is less than the binding energy of the first halogen species.

In some embodiments, the techniques described herein may be performed on a substrate having a silicon semiconductor portion and a silicon oxide dielectric portion. The modification operation may use a halogen species that includes chlorine which preferentially adsorbs on the silicon, without adsorbing with the dielectric portion (i.e., relative to the dielectric portion), to form the first halogenated semiconductor silicon tetrachloride (SiCl₄). The binding energy of the chlorine may be about 4.2 eV, the binding energy of the silicon may be about 3.4 eV, and the binding energy of the silicon oxide may be about 6.4 eV. This may prevent, or limit, the chlorine from adsorbing on the silicon oxide. In some instances, as mentioned above, the first activation energy during this modification operation may be thermal, plasma (e.g., a downstream plasma), or both.

In the removal operation, the second halogen species may be fluorine flowed onto the substrate as hydrogen fluoride (HF). The HF may react with the SiCl₄ to form silicon tetrafluoride (SiF₄) and hydrogen chloride (HCl). The HF may not react with, or have limited reactions with, the silicon oxide dielectric because, in some instances, at the second activation energy provided by thermal energy, may cause the absence of hydroxy groups which prevents or reduces this reaction. Also, at the second activation energy, the SiF₄ is caused to desorb from the substrate without desorbing the silicon oxide dielectric. This second activation energy may be heating the substrate to, for example, at least 100° C. In this example, SiF₄ is more volatile than SiCl₄.

In some embodiments, the first halogen species may include fluorine and the second species may include chlorine. In some such instances, the semiconductor may not be a semiconductor, but may be a metal-containing portion that may include a metal or a metal oxide that may comprise a titanium, and the dielectric portion may be silicon oxide. During the modification operation, the fluorine is flowed onto the substrate to preferentially adsorb on the metal-containing portion, here the titanium, without adsorbing with the dielectric portion (i.e., relative to the dielectric portion), to form halogenated titanium fluoride (TiF₃). During the removal operation, the chlorine is flowed onto the substrate to react with the TiF₃ and form titanium tetrachloride TiCl₄ which may desorb, relative to the dielectric from the substrate. In this example, TiCl₄ is more volatile than TiF₃. Additionally, the chlorine does not react with the dielectric portion and the dielectric portion is not removed from the subtrate.

“Silicon oxide” is referred to herein as including chemical compounds including silicon and oxygen atoms, including any and all stoichiometric possibilities for SiₓO_{y}, including integer values of x and y and non-integer values of x and y. For example, “silicon oxide” includes compounds having the formula SiOₙ, where 1≤ n≤2, where n can be an integer or non-integer values. “Silicon oxide” can include sub-stoichiometric compounds such as SiO_{1.8}. “Silicon oxide” also includes silicon dioxide (SiO₂) and silicon monoxide (SiO). “Silicon oxide” also includes both natural and synthetic variations and also includes any and all crystalline and molecular structures, including tetrahedral coordination of oxygen atoms surrounding a central silicon atom. “Silicon oxide” also includes amorphous silicon oxide and silicates.

The techniques and apparatuses described herein are able to selectively etch one or more layers of various semiconductor materials, relative to dielectrics. i.e., with limited or no removal of the dielectrics. For instance, semiconductor materials, such as silicon, may be etched without etching (i.e., relative to) dielectrics such as oxides, nitrides, metals, and metal oxides, such as silicon oxide and silicon nitride. As described above, the first halogen species used in the modification operation is selected to preferentially chemisorb with the molecules of the material that are to be ultimately removed from the substrate and not to chemisorb with other materials that are intended to remain on the substrate. Similarly, the second halogen species used in the removal operation may be selected to react with and cause the removal of the first halogenated semiconductor, and thus the removal of the semiconductor, from the substrate and not react with the other materials that are intended to remain on the substrate.

### ALE Apparatuses

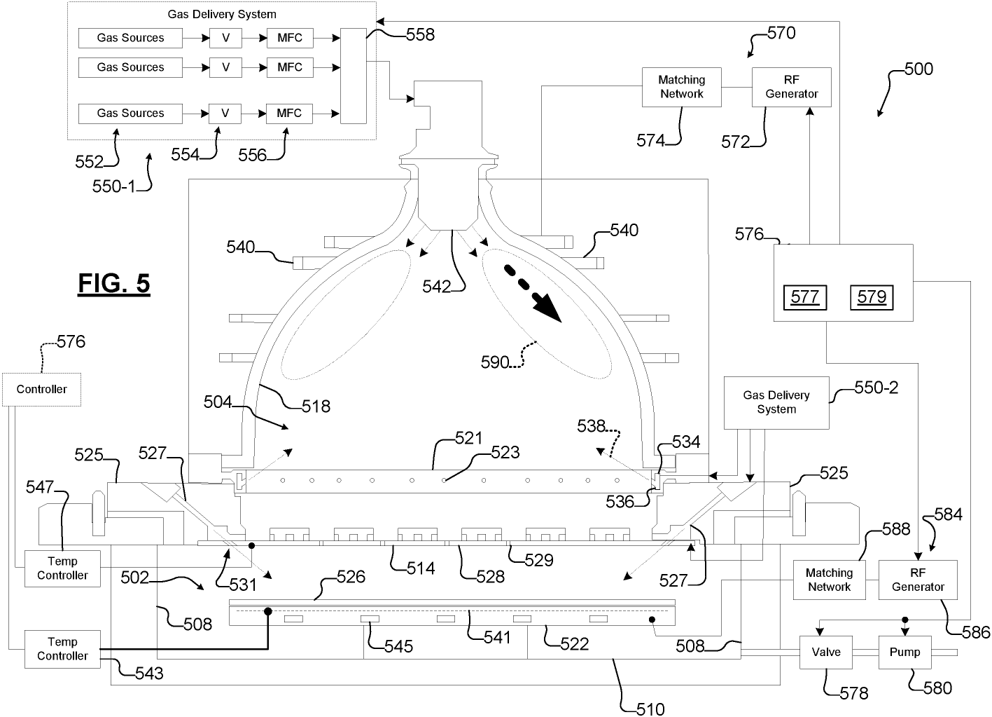

Referring now to FIG. 5, an example of a substrate processing chamber 500 for selectively etching a first material with respect to a second material according to the present disclosure is shown. While a specific substrate processing chamber is shown and described, the methods described herein may be implemented on other types of substrate processing systems. In some examples, the substrate processing chamber 500 includes a remote (e.g., upstream from the substrate) inductively coupled plasma (ICP) source. An optional capacitively coupled plasma (CCP) source may be provided.

The substrate processing chamber 500 includes a lower chamber region 502 and an upper chamber region 504. The lower chamber region 502 is defined by chamber sidewall surfaces 508, a chamber bottom surface 510 and a lower surface of a gas distribution device 514. In some examples, the gas distribution device 514 is omitted.

The upper chamber region 504 is defined by an upper surface of the gas distribution device 514 and an inner surface of an upper chamber wall 518 (for example a dome-shaped chamber). In some examples, the upper chamber wall 518 rests on a first annular support 521. In some examples, the first annular support 521 includes one or more gas flow channels and/or holes 523 for delivering process gas to the upper chamber region 504, as will be described further below. The gas flow channels and/or holes 523 may be uniformly spaced around a periphery of the upper chamber region 504. In some examples, the process gas is delivered by the one or more gas flow channels and/or holes 523 in an upward direction at an acute angle relative to a plane including the gas distribution device 514, although other angles/directions may be used. In some examples, a plenum 534 in the first annular support 521 supplies gas to the one or more spaced gas flow channels and/or holes 523.

The first annular support 521 may rest on a second annular support 525 that defines one or more gas flow channels and/or holes 527 for delivering process gas to the lower chamber region 502. In some examples, holes 531 in the gas distribution device 514 align with the gas flow channels and/or holes 527. In other examples, the gas distribution device 514 has a smaller diameter and the holes 531 are not needed. In some examples, the process gas is delivered by the one or more spaced gas flow channels and/or holes 527 in a downward direction towards the substrate at an acute angle relative to the plane including the gas distribution device 514, although other angles/directions may be used.

In other examples, the upper chamber region 504 is cylindrical with a flat top surface and one or more flat inductive coils may be used. In still other examples, a single chamber may be used with a spacer located between a showerhead and the substrate support.

A substrate support 522 is arranged in the lower chamber region 502. In some examples, the substrate support 522 includes an electrostatic chuck (ESC), although other types of substrate supports can be used. A substrate 526 is arranged on an upper surface of the substrate support 522 during etching. In some examples, a temperature of the substrate 526 may be controlled by a heater 541, or heater plate, an optional cooling plate with fluid channels and one or more sensors (not shown); although any other suitable substrate support temperature control system may be used. In some examples, a temperature controller 543 may be used to control heating and cooling of the substrate support 522. Heating may be performed by the heater 541 and cooling may be performed by the cooling plate with fluid channels 545.

A temperature controller 547 may be used to control a temperature of the gas distribution device 514 by supplying heating/cooling fluid to a plenum in the gas distribution device 514. The temperature controllers 543 and/or 547 may further include a source of fluid, a pump, control valves and a temperature sensor (all not shown).

In some examples, the gas distribution device 514 includes a showerhead (for example, a plate 528 having a plurality of spaced holes 529). The plurality of spaced holes 529 extend from the upper surface of the plate 528 to the lower surface of the plate 528. In some examples, the spaced holes 529 have a diameter in a range from 0.4” to 0.75” and the showerhead is made of a conducting material such as aluminum or a non-conductive material such as ceramic with an embedded electrode made of a conducting material. In other examples described further below, smaller holes 529 can be used to increase the surface to volume ratio.

One or more inductive coils 540 are arranged around an outer portion of the upper chamber wall 518. When energized, the one or more inductive coils 540 create an electromagnetic field inside of the upper chamber wall 518. In some examples, an upper coil and a lower coil are used. A gas injector 542 injects one or more gas mixtures from a gas delivery system 550-1 into the upper chamber region 504.

In some examples, a gas delivery system 550-1 includes one or more gas sources 552, one or more valves 554, one or more mass flow controllers (MFCs) 556, and a mixing manifold 558, although other types of gas delivery systems may be used. A gas splitter (not shown) may be used to vary flow rates of a gas mixture. Another gas delivery system 550-2 may be used to supply an etch gas, tuning gas, purge gas or other gas mixtures to the gas flow channels and/or holes 523 and/or 527 (in addition to or instead of etch gas from the gas injector 542). The gas delivery system 550-1 may a process gas unit configured to flow a first process gas comprising a first halogen species (e.g., fluorine, chlorine, bromine, or iodine) and a second process gas comprising a second halogen species (e.g., fluorine, chlorine, bromine, or iodine) into the chamber interior and onto the substrate in the chamber interior.

Suitable gas delivery systems are shown and described in commonly assigned U.S. Pat. Application Serial No. 14/945,680, entitled “Gas Delivery System” and filed on Dec. 4, 2015, which is hereby incorporated by reference in its entirety. Suitable single or dual gas injectors and other gas injection locations are shown and described in commonly assigned U.S. Provisional Pat. Application Serial No. 62/275,837, entitled “Substrate Processing System with Multiple Injection Points and Dual Injector” and filed on Jan. 7, 2016, which is hereby incorporated by reference in its entirety.

In some examples, the gas injector 542 includes a center injection location that directs gas in a downward direction and one or more side injection locations that inject gas at an angle with respect to the downward direction. In some examples, the gas delivery system 550-1 delivers a first portion of the gas mixture at a first flow rate to the center injection location and a second portion of the gas mixture at a second flow rate to the side injection location(s) of the gas injector 542. In other examples, different gas mixtures are delivered by the gas injector 542. In some examples, the gas delivery system 550-2 delivers tuning gas to the gas flow channels and/or holes 523 and 527 and/or to other locations in the processing chamber as will be described below. For example, the gas delivery system 550-2 can also deliver gas to a plenum in the gas distribution device 514.

A plasma generator 570 may be used to generate RF power that is output to the one or more inductive coils 540. Plasma 590 is generated in the upper chamber region 504. In some examples, the plasma generator 570 includes an RF generator 572 and a matching network 574. The matching network 574 matches an impedance of the RF generator 572 to the impedance of the one or more inductive coils 540. In some examples, the gas distribution device 514 is connected to a reference potential such as ground. A valve 578 and a pump 580 may be used to control pressure inside of the lower and upper chamber regions 502, 504 and to evacuate reactants.

A controller 576 communicates with the gas delivery systems 550-1 and 550-2, the valve 578, the pump 580, and/or the plasma generator 570 to control flow of process gas, purge gas, tuning gas, RF plasma and chamber pressure. In some examples, plasma is sustained inside the upper chamber wall 518 by the one or more inductive coils 540. One or more gas mixtures are introduced from a top portion of the chamber using the gas injector 542 (and/or gas flow channels and/or holes 523) and plasma is confined within the upper chamber wall 518 using the gas distribution device 514.

Confining the plasma in the upper chamber wall 518 allows volume recombination of plasma species and effusing desired etchant species through the gas distribution device 514. In some examples, there is no RF bias applied to the substrate 526. As a result, there is no active sheath on the substrate 526 and ions are not hitting the substrate with any finite energy. Some amount of ions will diffuse out of the plasma region through the gas distribution device 514. However, the amount of plasma that diffuses is an order of magnitude lower than the plasma located inside the upper chamber wall 518. Most of ions in the plasma are lost by volume recombination at high pressures. Surface recombination loss at the upper surface of the gas distribution device 514 also lowers ion density below the gas distribution device 514.

In some examples, an RF bias generator 584 is provided and includes an RF generator 586 and a matching network 588. The RF bias can be used to create plasma between the gas distribution device 514 and the substrate support or to create a self-bias on the substrate 526 to attract ions. The controller 576 may be used to control the RF bias.

The controller 576 is configured to control various aspects of the apparatus in order to perform the techniques described herein. The controller 576 (which may include one or more physical or logical controllers) is communicatively connected with and that controls some or all of the operations of a processing chamber. The controller 576 may include one or more non-transitory memory devices 577 and one or more processors 579. In some embodiments, the apparatus includes a switching system for controlling flow rates and durations, the substrate heating unit, the substrate cooling unit, the loading and unloading of a substrate in the chamber, the positioning of the substrate, and the process gas unit, for instance, when disclosed embodiments are performed. In some embodiments, the apparatus may have a switching time of up to about 500 ms, or up to about 750 ms. Switching time may depend on the flow chemistry, recipe chosen, reactor architecture, and other factors.

In some implementations, the controller 576 is part of an apparatus or a system, which may be part of the above-described examples. Such systems or apparatuses can include semiconductor processing equipment, including a processing tool or tools, chamber or chambers, a platform or platforms for processing, and/or specific processing components (a gas flow system, a substrate heating unit, a substrate cooling unit, etc.). These systems may be integrated with electronics for controlling their operation before, during, and after processing of a semiconductor wafer or substrate. The electronics may be referred to as the “controller,” which may control various components or subparts of the system or systems. The controller 576, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 576 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing operations during the fabrication of one or more layers, materials, metals, oxides, silicon, silicon dioxide, surfaces, circuits, and/or dies of a wafer.

The controller 576, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing operations to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 576 receives instructions in the form of data, which specify parameters for each of the processing operations to be performed during one or more operations. It should be understood that the parameters may be specific to the type of process to be performed and the type of tool that the controller is configured to interface with or control. Thus as described above, the controller 576 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

As noted above, depending on the process operation or operations to be performed by the apparatus, the controller 576 might communicate with one or more of other apparatus circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

As also stated above, the controller is configured to perform any technique described above. This may include causing a substrate transfer robot to position the substrate in the chamber. This may also include instructions to cause the process gas unit to flow the first process gas onto the substrate, cause, while flowing the first process gas onto the substrate, a first energy unit to provide the first activation energy to the substrate to cause the first halogen species to preferentially adsorb on the semiconductor portion relative to the dielectric portion to form a halogenated semiconductor. The first energy unit may be the heater 541, the plasma generator 570, or both. The controller 576 may also include instructions to cause the process gas unit to flow the second process gas onto the substrate, and cause, while flowing the second process gas onto the substrate, the second energy unit to provide the second activation energy to the substrate to cause the second halogen species to react with the first halogenated semiconductor and cause the first halogenated semiconductor to desorb from the substrate. The second energy unit may be the heater 541, the plasma generator 570, or both.

While the subject matter disclosed herein has been particularly described with respect to the illustrated embodiments, it will be appreciated that various alterations, modifications and adaptations may be made based on the present disclosure, and are intended to be within the scope of the present invention. It is to be understood that the description is not limited to the disclosed embodiments but, on the contrary, is intended to cover various modifications and equivalent arrangements included within the scope of the claims.

What is claimed is:

1. A method, comprising:
providing a substrate to a processing chamber, the substrate having a semiconductor portion and a dielectric portion;
modifying the semiconductor portion of the substrate selective to the dielectric portion of the substrate by flowing a first process gas comprising a first halogen species onto the substrate and providing a first activation energy to cause the first halogen species to preferentially adsorb on the semiconductor portion relative to the dielectric portion to form a first halogenated semiconductor; and
removing the first halogenated semiconductor by flowing a second process gas comprising a second halogen species onto the substrate and providing a second activation energy, without providing a plasma, to cause the second halogen species to react with the first halogenated semiconductor and cause the first halogenated semiconductor to desorb from the substrate.

2. The method of claim 1, wherein during the removing:
the second halogen species reacts with the first halogenated semiconductor to convert the first halogenated semiconductor to a second halogenated semiconductor, and
the desorption of the first halogenated semiconductor includes desorption of the second halogenated semiconductor.

3. The method of claim 2, wherein the second halogenated semiconductor is more volatile than the first halogenated semiconductor.

4. The method of claim 2, wherein:
the first halogen species comprises chlorine,
the first halogenated semiconductor comprises silicon tetrachloride (SiCl₄),
the second halogen species comprises fluorine, and
the second halogenated semiconductor comprises silicon tetrafluoride (SiF₄).

5. The method of claim 1, wherein the semiconductor portion comprises one or more of silicon, germanium, silicon-germanium, or a doped silicon.

6. The method of claim 1, wherein the dielectric portion comprises one or more of an oxide or a nitride.

7. The method of claim 1, wherein, at the first activation energy, the semiconductor portion is halogenated by the first halogen species without halogenating the dielectric portion.

8. The method of claim 7, wherein, at the second activation energy, the first halogenated semiconductor is removed by a reaction with the second halogen species without removing the dielectric portion.

9. The method of claim 1, wherein providing the first activation energy is provided by heating the substrate to a temperature.

10. The method of claim 9, wherein the first temperature is greater than about 100° C.

11. The method of claim 9, wherein:
the first activation energy is provided by heating the substrate and by a plasma, and
the first temperature is less than or equal to about 250° C.

12. The method of claim 11, wherein the first temperature is less than or equal to about 150° C.

13. The method of claim 1, wherein providing the first activation energy is provided by a plasma.

14. The method of claim 1, wherein the second activation energy is provided, without using a plasma, by heating the substrate to a temperature.

15. The method of claim 14, wherein the temperature is greater than or equal to about 100° C.

16. The method of claim 1, wherein the modifying is performed while the substrate is maintained at a temperature less than or equal to about 150° C.

17. The method of claim 1, wherein the removing is performed while the substrate is maintained at a temperature greater than or equal to about 100° C.

18. The method of claim 1, wherein the first and second halogen species each comprise a different halogen species selected from the group consisting of fluorine, chlorine, bromine, and iodine.

19. The method of claim 1, wherein:
the first halogen species comprises chlorine, and
the second halogen species comprises fluorine.

20. The method of claim 1, wherein:
the first halogen species comprises fluorine, and
the second halogen species comprises chlorine.

21. The method of claim 1, wherein:
the first process gas comprises chlorine (Cl₂), and
the second process gas comprises hydrogen fluoride (HF).

22. The method of claim 1, wherein the semiconductor portion comprises silicon.

23. The method of claim 22, wherein the dielectric portion comprises a silicon oxide or a silicon nitride.

24. The method of claim 1, wherein the modification of the semiconductor portion and/or the removal of the first halogenated semiconductor occurs isotropically.

25. The method of claim 1, wherein the semiconductor portion does not comprise a silicon oxide.

26. The method of claim 1, further comprising flowing, before or during the removing, a catalyst onto the substrate, wherein the catalyst is configured to assist with the reaction between the second halogen species and the first halogenated semiconductor.

27. A method, comprising:
providing a substrate to a processing chamber, the substrate having a metal-containing portion and a dielectric portion;
modifying the metal-containing portion of the substrate selective to the dielectric portion of the substrate by flowing a first process gas comprising a first halogen species onto the substrate and providing a first activation energy to cause the first halogen species to preferentially adsorb on the metal-containing portion relative to the dielectric portion to form a halogenated metal-containing portion; and
removing the halogenated metal-containing portion by flowing a second process gas comprising a second halogen species onto the substrate and providing a second activation energy, without providing a plasma, to cause the second halogen species to react with the halogenated metal-containing portion and cause the halogenated metal-containing portion to desorb from the substrate.

28. The method of claim 27, wherein the metal-containing portion includes a metal or a metal oxide.

29. The method of claim 27, wherein, at the first activation energy, the metal-containing portion is halogenated by the first halogen species without halogenating the dielectric portion.

30. The method of claim 27, wherein, at the second activation energy, the first halogenated metal-containing portion is removed by a reaction with the second halogen species without removing the dielectric portion.

31. The method of claim 27, wherein:
the first halogen species comprises fluorine, and
the second halogen species comprises chlorine.

32. An apparatus for semiconductor processing, the apparatus comprising:
a processing chamber that includes chamber walls that at least partially bound a chamber interior, and substrate support configured to support a substrate in the chamber interior;
a process gas unit configured to flow a first process gas comprising a first halogen species and a second process gas comprising a second halogen species into the chamber interior and onto the substrate in the chamber interior, wherein the substrate has a semiconductor portion and a dielectric portion;
a first energy unit configured to provide a first activation energy to the substrate on the substrate support;
a second energy unit configured to provide a second activation energy to the substrate on the substrate support; and
a controller with instructions that are configured to:
cause the process gas unit to flow the first process gas onto the substrate,
cause, while flowing the first process gas onto the substrate, the first energy unit to provide the first activation energy to the substrate to cause the first halogen species to preferentially adsorb on the semiconductor portion relative to the dielectric portion to form a halogenated semiconductor,
cause the process gas unit to flow the second process gas onto the substrate, and
cause, while flowing the second process gas onto the substrate, the second energy unit to provide the second activation energy to the substrate to cause the second halogen species to react with the halogenated semiconductor and cause the halogenated semiconductor to desorb from the substrate.

33. The apparatus of claim 32, wherein the first energy unit is a heater and the second energy unit is the heater.

34. The apparatus of claim 32, wherein:
the first energy unit is configured to generate a plasma,
the second energy unit is a heater,
the first activation energy is a plasma energy generated by the first energy unit, and
the second activation energy is provided by causing the heater to heat the substrate to a first temperature.

35. The apparatus of claim 34, wherein the first temperature is greater than about 100° C.
